(19) United States
(12) Patent Application Publication
(10) Pub. No.: US 2002/0074652 A1
(43) Pub. Date: Jun. 20, 2002

(54) Method, apparatus and system for multiple chip assemblies

(76) Inventor: John L. Pierce, Dallas, TX (US)

Correspondence Address: Daniel J. Chalker, Gardere Wynne Sewell L.L.P., 3000 Thanksgiving Tower, 1601 Elm Street, Dallas, TX, 75201-4761, US

(21) Appl. No.: 09/738,201

(22) Filed: Dec. 15, 2000

(51) Int. Cl. H01L 25/00; H01L 21/44; H01L 21/48; H01L 21/50

(52) U.S. Cl. 257/724; 438/107; 438/108; 438/599

(57) ABSTRACT

The present invention provides a three-dimensional chip assembly and the corresponding methods for producing such an assembly. The present invention utilizes flip chip technology, i.e., using solder balls to directly connect the chip to the substrate, to create chip assemblies that can be arranged in horizontal arrays of varying geometries as well as being stacked at chosen points in such arrays to produce a three dimensional array or assembly of semiconductor chips. Since the designer can specify the geometry of the arrays, this invention allows the creation of customized three-dimensional chip assemblies that maximize the internal space utilization of the devices that they are integrated into.

### FIELD OF THE INVENTION

The present invention relates in general to the field of semiconductor devices, and more particularly to a method, apparatus and system for multiple chip assemblies.

### BACKGROUND OF THE INVENTION

Without limiting the scope of the invention, its background is described in connection with personal electronic devices, as an example. Most electronic devices use semiconductor memory and logic chips to enable specific functionality. Many of these devices are portable computing or consumer related devices. Examples are Personal Digital Assistants (PDA's), telephones (cellular, mobile, portable), notebook computers, digital cameras, remote controls, game consoles and music and video players.

As new features and capabilities are added to portable devices such as those described above, more computing power and memory are required. In addition, the size of these portable electronic devices are becoming smaller and smaller with each new generation. As a result, space within these portable devices is very limited.

A good example is the digital camera. The pixel size of digital photographs has steadily increased from 640,000 pixels to 3,300,000 pixels. The photographs taken with a digital camera are stored in on-board memory until they can be downloaded to a computer. The desire of consumers to store larger numbers of bigger pictures has lead to a need for greater amounts of on-board memory.

The current solution for providing memory for portable electronic devices is grouping memory chips in very small packages (such as Chip Scale Packages) and mounting these packages on printed circuit boards (PCB's). This is necessarily a two-dimensional solution. The PCB must be expanded in length and/or width in order to allow for the attachment of more memory packages. The designer of a personal electronic device thus is faced with making a compromise between the amount of memory that a device will accommodate, and the overall size of the device as dictated by the size of the PCB.

The current approach to making three-dimensional boards involves stacking semiconductor chips or die, and connecting them by running connective traces along the stack of semiconductor dies. Although this approach increases the number of memory or logic chips in a given location on a PCB, it has disadvantages. For example, the added connective traces between the chips in the stack requires additional processing that increases the cost, thus making this method cost prohibitive for personal electronic devices. The additional processing is also very complex, and as a result, the yield of functional chip stacks is too low to make this an economical solution. Another problem with this technique is that it only allows the expansion of the chip stack in one direction since only the height of the stack can be altered.

There is, therefore, a need for an invention that allows semiconductor chips to be mounted in a three-dimensional configuration specified by a designer. In addition, there is a need for an invention that utilizes high-yielding processes which makes its use in consumer applications advantageous.

### SUMMARY OF THE INVENTION

Generally, and in one form of the invention, a multiple chip assembly is formed on a substrate that has an upper and a lower surface. A semiconductor die is attached to each surface. A second and a third substrate are attached to the lower side of the first substrate between the semiconductor die and the outer edge of the lower surface, such that the second and third substrates are parallel to one another. A first set of one or more electrical pathways pass through the first and second substrates, and a second set of additional electrical pathways connect the semiconductor dies to the first set of electrical pathways.

In another form of the invention, a third set of electrical pathways passes through the first and third substrates. A fourth set of electrical pathways connects the semiconductor dies to the third set of electrical pathways.

In yet another form of the invention, a fourth and a fifth substrate are attached to the upper surface of the first substrate between the semiconductor die and the outer edges of the upper surface. The fourth and fifth substrates are vertically aligned with the second and third substrates. The first and third sets of electrical pathways are extended to pass through the first, second and fourth substrates; and the first, third and fifth substrates, respectively.

In still another form of the invention, a system of three-dimensional chip multiple chip assemblies are formed by creating substrate interconnection pads at the termini of the first and third sets of electrical pathways of the multiple chip assemblies described above. Solder balls are then placed on at least one set of the interconnection pads, i.e. those associated with the top surface of the first substrate, or those associated with the bottom surface of the first substrate. The individual multiple chips assemblies are then aligned in stacks such that the interconnection pads associated with the lower surface of one multiple chip assembly correspond to the position of the interconnection pads associated with the upper surface of another multiple chip assembly. The stack is then heated so that a solder joint is created between the two multiple chip assemblies.

The semiconductor die arrangement can be customized in length, width and height across the surface of a printed circuit board. This allows for the utilization of empty internal space in existing designs, as well as the creation of novel designs not possible when only a two-dimensional method is used.

### BRIEF DESCRIPTION OF THE DRAWINGS

The above and further advantages of the invention may be better understood by referring to the following description in conjunction with the accompanying drawings in which the corresponding numerals in the different figures refer to corresponding parts in which:

FIG. 1A shows a void space above a printed circuit board;

FIG. 1B shows the void space filled with multiple chip assemblies in accordance with the present invention;

FIG. 2 is a side view of one form of a multiple chip assembly in accordance with the present invention;

FIG. 3A is a side view of another form of a multiple chip assembly in accordance with the present invention;

FIG. 3B is a side view showing the stacking of another form of multiple chip assembly;

FIG. 4A is a side view of another form of multiple chip assembly in accordance with the present invention;

FIG. 4B is a side view showing the stacking of another form of multiple chip assembly;

FIG. 5A is a side view of another form of multiple chip assembly in accordance with the present invention;

FIG. 5B is a side view showing the stacking of another form of multiple chip assembly;

FIG. 6 is a top view of a panel containing multiple chip assemblies in accordance with the present invention;

FIG. 7 is a side view of a chip assembly showing interconnections in accordance with the present invention;

FIG. 8 is a top view that shows the vertical inter-connections of a chip assembly terminated as contact pads in accordance with the present invention;

FIG. 9 shows a simple vertical stack of chip assemblies mounted on a printed circuit boarding in accordance with the present invention; and

FIG. 10 demonstrates how differential stacking of chip assemblies can be utilized to fill an available space, as indicated by the dotted line in accordance with the present invention.

### DETAILED DESCRIPTION OF THE PREFERRED EMBODIMENTS

The invention, as defined by the claims, may be better understood by reference to the following detailed description. The description is meant to be read with reference to the drawings contained herein. This detailed description relates to an example of the claimed subject matter for illustrative purposes, and is in no way meant to limit the scope of the invention.

The present invention provides a multiple chip assembly, and the corresponding methods for producing such an assembly, that address the previously mentioned problems related to space utilization in small electronic devices. Specifically, the present invention utilizes flip chip technology, i.e., using solder balls to directly connect the chip to the substrate, and to create chip assemblies that can be arranged in horizontal arrays of varying geometries as well as being stacked at chosen points in such arrays to produce a three dimensional array or assembly of semiconductor chips. Since the designer can specify the geometry of the arrays, this invention allows the creation of customized three-dimensional chip assemblies that maximize the internal space utilization of the devices that they are integrated into.

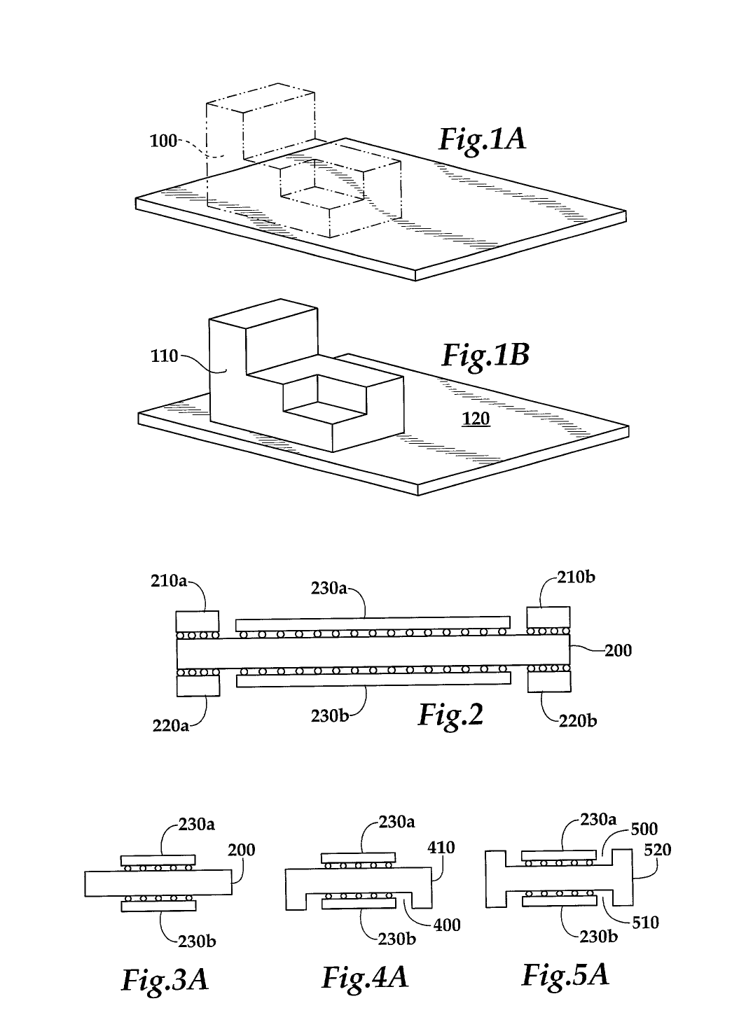

FIG. 1 shows one embodiment of the invention as it is envisioned when incorporated into a personal electronic device. A designer may take advantage of the void space, 1000, existing in a device by using it to house needed semiconductor elements in the form of multiple chip assemblies, 110 mounted to a printed circuit board, 120.

A preferred embodiment of the present invention is based on the chip assembly of FIG. 2, that is used as a building block for creating custom designed semiconductor chip stacks as seen in FIGS. 1, 9 and 10, that results in a three-dimensional multiple chip assembly.

The building blocks of the invention are single chip assemblies as shown in FIGS. 2, 3A, 4A and 5A. Although not depicted in the figures, underfill can be used in any form of the present invention. In one embodiment, shown in FIG. 2, the chip assembly is composed of five substrates and two semiconductor dies. Substrates 210a and 210b are attached to substrate 200, along with, and at the same time as semiconductor die 230a is attached. The attachments are made using flip chip technology. Substrates 220a and 220b, and semiconductor die 230b are also attached during the same flip chip assembly operation. The entire assembly represented in FIG. 2 forms a multiple chip assembly. There are no inherent design restrictions on the dimensions of substrates 200, 210 or 220, so that they may be tailored to any need. The solder balls that connect the semiconductor dies, 230, and substrates 210 and 220 to substrate 200 can all be the same size, although they are not required to be. Using uniform solder balls facilitates the assembly process by simplifying both the design and assembly of the multiple chip assemblies. It is also possible to construct chip assemblies in which substrates 210 and 220 are not used.

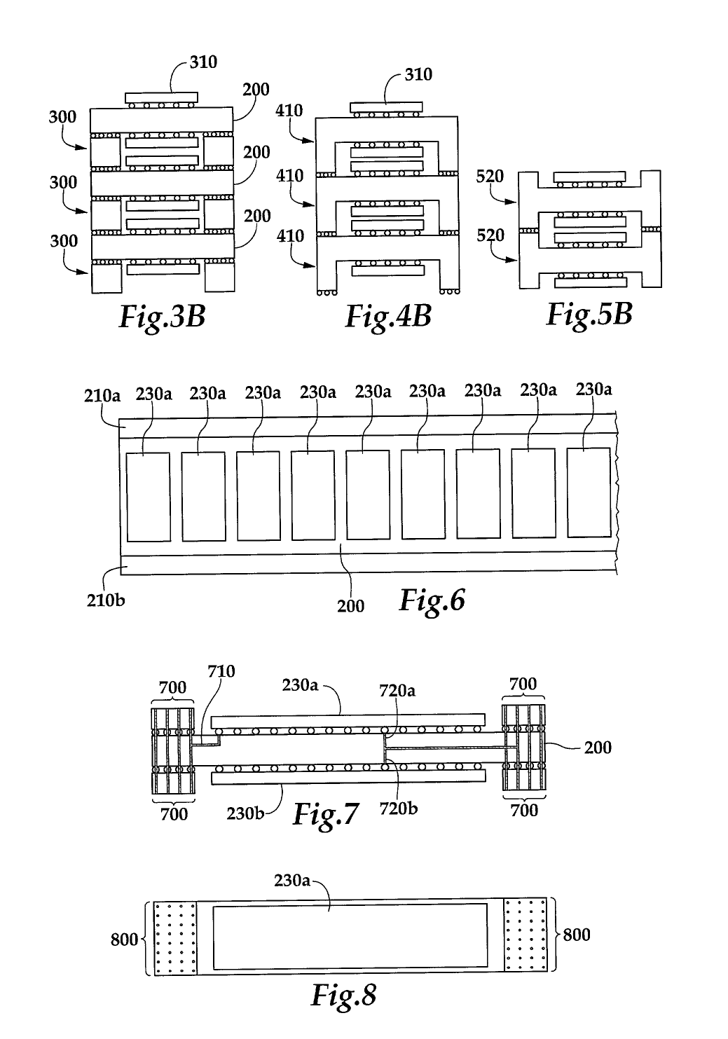

FIG. 3A is an example of a single substrate chip assembly in which two semiconductor dies, 230, are mounted to a single substrate, 200, using flip chip bonding techniques.

FIG. 3B depicts a stack of multiple chip assemblies based on the single substrate form of the invention shown in FIG. 3A. The substrate, 200, of each multiple chip assembly is connected to the corresponding substrate 200 of the next chip assembly using flip chip technology. A spacer substrate, 300, is used to build the stack and interconnect the individual chip assemblies. The stack is shown being capped by a single semiconductor die, 310, however, the use of this die is optional.

A single substrate can also be used in which the semiconductor dies are mounted in cavities in the substrate. FIG. 4 shows a chip assembly in which one semiconductor dies, 230b, is mounted in a single cavity, 400, in substrate 410. It is also possible to place semiconductor dies, 230a and 230b, in cavities, 500 and 510, in substrate 520, as shown in FIG. 5A.

FIG. 4B depicts a stack of multiple chip assemblies based on the single substrate form of the invention shown in FIG. 4A. The substrate, 410, of each multiple chip assembly is connected to the corresponding substrate 410 of the next chip assembly using flip chip technology. The stack is shown being capped by a single semiconductor die, 310, however, the use of this semiconductor die is optional.

FIG. 5B depicts a stack of multiple chip assemblies based on the single substrate form of the invention shown in FIG. 5A. The substrate, 520, of each multiple chip assembly is connected to the corresponding substrate 520 of the next chip assembly using flip chip technology.

In order to achieve cost efficiencies, a panel of dies and substrates can be assembled during one manufacturing operation. FIG. 6 shows the top of such a panel. In a single operation substrates 210a and 210b along with a number of semiconductor dies, 230a, are attached to substrate 200. Subsequently, substrates 220a and 220b, along with dies 230b would be attached in a similar manner to the opposite side of substrate 200. Once both sides of the panel are fully assembled, a slicing operation could be used to separate the individual chip assemblies.

The semiconductor dies used to make up the panels need not be all of the same type, e.g. memory chips. This is another example of the flexibility that this invention provides to a designer of compact electronic devices.

FIG. 7 shows details of possible internal connections within the chip assemblies. Attachment of the chip assembly to other chip assemblies, or to another printed circuit board is accomplished through vertical connectors, 700. In some cases the connector will make a connection to only one chip, as shown in connection 710. An example of a use for this type of connection would be a chip select function. In other cases, a connection will be made that communicates with both chips, as shown in connections 720a and 720b. These types of connections would be used, for example, for data input/output (I/O) or power connections. FIG. 7 shows connections 710 and 720 as being inside of substrate 200. This is only necessary if the number of connections required makes a multilayer substrate necessary. For most chip assembly applications, these connections can be routed on the surface of substrate 200, which greatly reduces assembly costs.

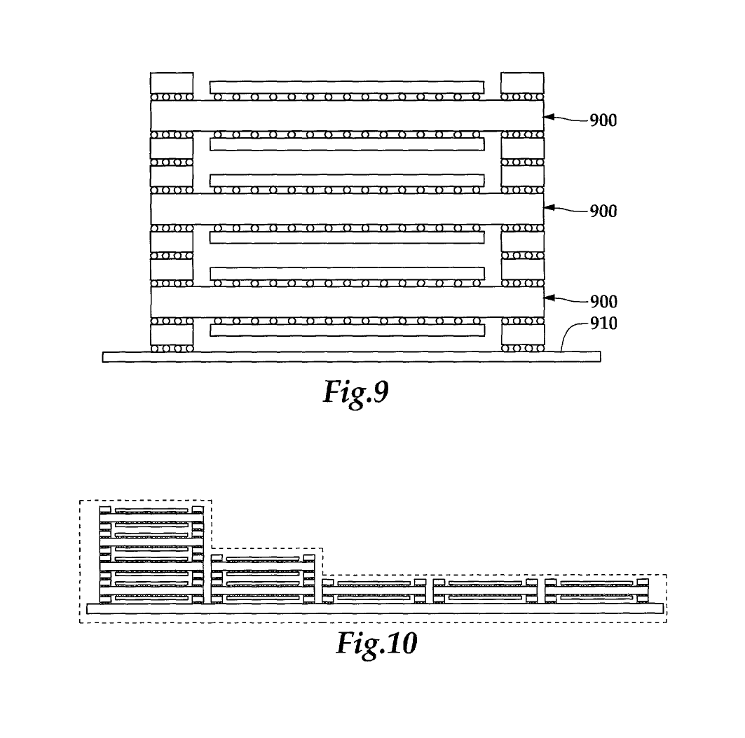

FIG. 8 shows a top view of a chip assembly. The vertical connectors are terminated on the top as contact pads, 800. These pads are suitable for connecting the chip assemblies to one another, as discussed below in conjunction with FIG. 9 The pads, 800, can also be used as contact points for electrical testing of the chip assemblies after they are constructed. In custom chip assembly stacks, the pads, 800, can be utilized to test for both the proper function of each individual chip in the stack as well as the quality of the interconnection of the individual chip assemblies into the stack. This testing can be performed prior to installation into a subassembly or end-use device. The inability to easily test flip chip mounted chips has been one of the major disadvantages of the technology.

Custom chip assemblies can be manufactured by combining multiple chip assemblies of various configurations, providing system designers a great deal of flexibility in designing portable electronic devices. The chip assemblies can be placed in any combination of vertical or horizontal configurations.

FIG. 9 shows a simple vertical stack of chip assemblies mounted onto a printed circuit board. Three chip assemblies, 900, are assembled together with solder balls and attached to printed circuit board 910. Attachment of the chip assemblies to one another, and to the printed circuit board can be accomplished in a single manufacturing operation.

It may be necessary to use circuit capacitors to prevent electrical noise from interfering with the performance of the custom chip assemblies. Capacitors as well as other noise suppression devices can be attached to the chip assemblies or the circuit board as required. The attachment of these additional components can occur at the same time in which the other components of the system are assembled.

FIG. 10 shows another possible configuration for a custom multiple chip assembly. In this arrangement there are four chip assemblies mounted vertically adjacent to two vertically mounted chip assemblies which are in turn mounted adjacent to three single chip assemblies. As shown, this array would fit within an existing space represented by the dotted line. This drawing represents a cross section of an array that could also extend longitudinally, thus creating a three-dimensional array.

Any configuration of horizontal or vertical stacking is possible. This flexibility will enable a maximum number of chips to be fit into applications where space is at a premium. This design capability coupled with the fact that the fabrication utilizes economical flip chip assembly techniques that result in a high yield of working product, provides the portable computing industry with a source of denser, more reliable and more cost effective chip assemblies.

While specific alternatives to steps of the invention have been described herein, additional alternatives not specifically disclosed but known in the art are intended to fall within the scope of the invention. Thus it is understood that other applications of the apparent invention will be apparent to those skilled in the art upon the reading of the described embodiment and a consideration of the appended claims and drawings.

What is claimed is:

1. A multiple chip assembly comprising:
a first substrate having an upper surface and a lower surface
a first semiconductor die mounted to the upper surface of the first substrate;
a second semiconductor die mounted to the lower surface of the first substrate;
a second substrate mounted to the lower surface of the first substrate between the second semiconductor and an outer edge of the lower surface;
a third substrate mounted to the lower surface of the first substrate between the second semiconductor and an opposite outer edge of the lower surface;
one or more first electrical pathways passing through the first substrate and the second substrate;
one or more second electrical pathways connecting the first semiconductor die to the one or more first electrical pathways; and
one or more third electrical pathways connecting the second semiconductor die to the one or more first electrical pathways.

2. The multiple chip assembly as recited in claim 1, further comprising:
one or more fourth electrical pathways passing through the first substrate and the third substrate;
one or more fifth electrical pathways connecting the first semiconductor die to the one or more fourth electrical pathways; and
one or more sixth electrical pathways that connect the second semiconductor die to the one or more fourth electrical pathways.

3. The multiple chip assembly as recited in claim 1, wherein at least one of the second electrical pathways are within the first substrate.

4. The multiple chip assembly as recited in claim 1, wherein at least one of the third electrical pathways are within the first substrate.

5. The multiple chip assembly as recited in claim 2, wherein at least one of the fifth electrical pathways are within the first substrate.

6. The multiple chip assembly as recited in claim 2, wherein at least one of the sixth electrical pathways are within the first substrate.

7. The multiple chip assembly as recited in claim 1, further comprising:
a fourth substrate mounted to the upper surface of the first substrate between the semiconductor die and an outer edge of the upper surface, and vertically aligned with the second substrate; and
a fifth substrate mounted to the upper surface of the first substrate between the first semiconductor die and an opposite outer edge of the upper surface, and vertically aligned with the third substrate.

8. The multiple chip assembly as recited in claim 7 wherein at least one of the first electrical pathways also passes through the fourth substrate.

9. The multiple chip assembly as recited in claim 2, further comprising:
a fourth substrate mounted to the upper surface of the first substrate between the semiconductor die and an outer edge of the upper surface, and vertically aligned with the second substrate; and
a fifth substrate mounted to the upper surface of the first substrate between the first semiconductor die and an opposite outer edge of the upper surface, and vertically aligned with the third substrate.

10. The multiple chip assembly recited in claim 9 wherein at least one of the fourth electrical pathways also passes through the fifth substrate.

11. The multiple chip assembly as recited in claim 9, wherein at least one of the first electrical pathways also passes through the fourth substrate.

12. The multiple chip assembly as recited in claim 10, further comprising one or more seventh electrical pathways passing through the first substrate and connecting the first semiconductor die to the second semiconductor die.

13. The multiple chip assembly as recited in claim 9, further comprising one or more seventh electrical pathways passing through the first substrate and connecting the first semiconductor die to the second semiconductor die.

14. A multiple chip assembly comprising:
a first substrate having an upper surface and a lower surface;
a first semiconductor die mounted to the upper surface of the first substrate;
a second semiconductor die mounted to the lower surface of the first substrate;
a second substrate mounted to the lower surface of the first substrate between the first semiconductor die and an outer edge of the lower surface;
a third substrate mounted to the lower surface of the first substrate between the first semiconductor die and an opposite outer edge of the lower surface;
a fourth substrate mounted to the upper surface of the first substrate between the second semiconductor and an outer edge of the upper surface, and vertically aligned with the second substrate;
a fifth substrate mounted to the upper surface of the first substrate between the second semiconductor and an opposite outer edge of the upper surface, and vertically aligned with the third substrate;
one or more first electrical pathways passing through the first substrate and the second substrate;
one or more second electrical pathways connecting the first semiconductor die to the one or more first electrical pathways;
one or more third electrical pathways connecting the second semiconductor die to the one or more first electrical pathways;
one or more fourth electrical pathways passing through the first substrate and the second substrate;
one or more fifth electrical pathways connecting the first semiconductor die to the one or more fourth electrical pathways; and
one or more sixth electrical pathways connecting the second semiconductor die to the one or more fourth electrical pathways.

15. The multiple chip assembly as recited in claim 14, further comprising one or more seventh electrical pathways passing through the first substrate and connecting the first semiconductor die to the second semiconductor die.

16. A multiple chip assembly comprising:
a first substrate having an upper surface and a lower surface;
a first semiconductor die mounted to the upper surface of the first substrate;
a second semiconductor die mounted to the lower surface of the first substrate;
a second substrate mounted to the lower surface of the first substrate between the semiconductor die and the outer edge of the lower surface;
a third substrate mounted to the lower surface of the first substrate between the first semiconductor die and the outside edge of the lower surface;
a fourth substrate mounted to the upper surface of the first substrate between the second semiconductor and the outer edge of the upper surface, and vertically aligned with the second and third substrates;
a fifth substrate mounted to the upper surface of the first substrate between the second semiconductor and the outer edge of the upper surface, and vertically aligned with the second and third substrates;
one or more first electrical pathways passing through the first substrate and the second substrate;
one or more second electrical pathways connecting the first semiconductor die to the one or more first electrical pathways;
one or more third electrical pathways passing through the first substrate and the third substrate; and
one or more fourth electrical pathways connecting the second semiconductor die to the one or more third electrical pathways.

17. The multiple chip assembly as recited in claim 16, further comprising one or more fifth electrical pathways passing through the first substrate and connecting the first semiconductor die to the second semiconductor die.

18. A multiple chip assembly as recited in claim 17, wherein at least one of the one or more first electrical pathways also passes through the fourth substrate.

19. A multiple chip assembly as recited in claim 18, wherein at least one of the third electrical pathways also passes through the fifth substrate.

20. A method of manufacturing a multiple chip assembly comprising the steps of:
mounting a first semiconductor die on an upper surface of a first substrate;
mounting a second semiconductor die on a lower surface of the first substrate;
mounting a second substrate on the lower surface of the first substrate between the second semiconductor die and an outer edge of the lower surface;
mounting a third substrate on the lower surface of the first substrate between the second semiconductor die and an opposite outer edge of the lower surface;
creating one or more first electrical pathways through the first substrate and the second substrate;
creating one or more second electrical pathways connecting the first semiconductor die to the one or more first electrical pathways; and
creating one or more third electrical pathways connecting the second semiconductor die to the one or more first electrical pathways.

21. The method as recited in claim 20, further comprising the steps of:
creating one or more fourth electrical pathways through the first substrate and the third substrate;
creating one or more fifth electrical pathways connecting the first semiconductor die to the one or more fourth electrical pathways; and
creating one or more sixth electrical pathways connecting the second semiconductor die to the one or more fourth electrical pathways.

22. A multiple chip system comprising:
two or more chip assemblies;
each chip assembly comprising a first substrate having an upper surface and a lower surface, a first semiconductor die mounted to the upper surface of the first substrate, a second semiconductor die mounted to the lower surface of the first substrate, a second substrate mounted to the lower surface of the first substrate between the second semiconductor and an outer edge of the lower surface, a third substrate mounted to the lower surface of the first substrate between the second semiconductor and an opposite outer edge of the lower surface, a fourth substrate mounted to the upper surface of the first substrate between the semiconductor die and an outer edge of the upper surface and vertically aligned with the second substrate, a fifth substrate mounted to the upper surface of the first substrate between the first semiconductor die and an opposite outside edge of the upper surface and vertically aligned with the third substrate, one or more first electrical pathways passing through the first substrate and the second substrate, one or more second electrical pathways connecting the first semiconductor die to the one or more first electrical pathways, and one or more third electrical pathways connecting the second semiconductor die to the one or more first electrical pathways; and the two or more chip assemblies stacked such that the fourth substrate of a lower chip assembly is connected to the second substrate of an upper chip assembly, the fifth substrate of the lower chip assembly is connected to the third substrate of the upper chip assembly, and the first electrical pathways of the lower chip assembly are connected to the first electrical pathways of the upper chip assembly.

23. A multiple chip assembly comprising:
a substrate having an upper surface and a lower surface and a cavity in the lower surface;
a first semiconductor die mounted to the upper surface of the substrate;
a second semiconductor die mounted in the cavity in the lower surface of the substrate;
one or more first electrical pathways passing through the substrate between an outer edge of the cavity in the lower surface and a complimentary outer edge of the lower surface;
one or more second electrical pathways connecting the first semiconductor die to the one or more first electrical pathways; and
one or more third electrical pathways connecting the second semiconductor die to the one or more first electrical pathways.

24. The multiple chip assembly as recited in claim 23 further comprising:
one or more fourth electrical pathways passing through the substrate between an opposite outer edge of the cavity in the lower surface and a complimentary opposite outer edge of the lower surface;
one or more fifth electrical pathways connecting the first semiconductor die to the one or more fourth electrical pathways; and
one or more sixth electrical pathways connecting the second semiconductor die to the one or more fourth electrical pathways.

25. The multiple chip assembly as recited in claim 24, wherein at least one of second electrical pathways are within the substrate.

26. The multiple chip assembly as recited in claim 24, wherein at least one of the third electrical pathways are within the substrate.

27. The multiple chip assembly as recited in claim 24, wherein at least one of the one or more fifth electrical pathways are within the substrate.

28. The multiple chip assembly as recited in claim 24, wherein at least one of the sixth electrical pathways are within the substrate.

29. A multiple chip assembly comprising:
a substrate having an upper surface and a lower surface and a first cavity in the lower surface and a second cavity in the upper surface;
a first semiconductor die mounted in the first cavity of the substrate;
a second semiconductor die mounted in the second cavity in the substrate;
one or more first electrical pathways passing through the substrate between an outer edge of the first cavity and a complimentary outer edge of the lower surface, and between an outer edge of the second cavity and a complimentary outer edge of the upper surface;
one or more second electrical pathways connecting the first semiconductor die to the one or more first electrical pathways; and
one or more third electrical pathways connecting the second semiconductor die to the one or more first electrical pathways.

30. The multiple chip assembly as recited in claim 29 further comprising:
one or more fourth electrical pathways passing through the substrate between an opposite outer edge of the first cavity and a complimentary opposite outer edge of the lower surface, and between an outer edge of the second cavity and a complimentary outer edge of the upper surface;
one or more fifth electrical pathways connecting the first semiconductor die to the one or more fourth electrical pathways; and
one or more sixth electrical pathways that connect the second semiconductor die to the one or more fourth electrical pathways.

31. The multiple chip assembly as recited in claim 30, wherein at least one of the second electrical pathways are within the first substrate.

32. The multiple chip assembly as recited in claim 30, wherein at least one of the third electrical pathways are within the first substrate.

33. The multiple chip assembly as recited in claim 30, wherein at least one of the fifth electrical pathways are within the first substrate.

34. The multiple chip assembly as recited in claim 30, wherein at least one of the sixth electrical pathways are within the first substrate.

35. A method of manufacturing a multiple chip assembly comprising the steps of:
mounting a first semiconductor die on an upper surface of a first substrate;
mounting a second semiconductor die in a first cavity in a lower surface of the first substrate;
creating one or more first electrical pathways through the substrate between an outer edge of the first cavity and a complimentary outer edge of the lower surface, and between an outer edge of the second cavity and a complimentary outer edge of the upper surface;
creating one or more second electrical pathways connecting the first semiconductor die to the one or more first electrical pathways;
creating one or more third electrical pathways connecting the second semiconductor die to the one or more first electrical pathways.

36. The method as recited in claim 35, further comprising:
a second cavity in the upper surface of the substrate; and
the second semiconductor die mounted in the second cavity.

37. The method as recited in claim 35, further comprising the steps of:
creating one or more fourth electrical pathways through the substrate between an outer edge of the first cavity and a complimentary outer edge of the lower surface, and between an outer edge of the second cavity and a complimentary outer edge of the upper surface;
creating one or more fifth electrical pathways connecting the second semiconductor die to the one or more fourth electrical pathways; and
creating one or more sixth electrical pathways connecting the second semiconductor die to the one or more fourth electrical pathways.

38. The method recited in claim 37, further comprising:
a second cavity in the upper surface of the substrate; and
the second semiconductor die mounted in the second cavity.

39. A multiple chip system comprising:
two or more chip assemblies;
each chip assembly comprising a substrate having an upper surface and a lower surface and a first cavity in the lower surface, a first semiconductor die mounted in the first cavity of the substrate, a second semiconductor die mounted on the upper surface, one or more first electrical pathways passing through the surface of the substrate between an outer edge of the second cavity and a corresponding outer edge of the lower surface of the substrate, one or more second electrical pathways connecting the first semiconductor die to the one or more first electrical pathways, and one or more third electrical pathways connecting the second semiconductor die to the one or more first electrical pathways; and the two or more chip assemblies stacked such that the upper surface of the a lower chip assembly is connected to the lower surface of an upper chip assembly, and the first electrical pathways of the lower chip assembly are connected to the first electrical pathways of the upper chip assembly.

40. The system as recited in claim 39 further comprising:
a second cavity in the upper surface of the substrate; and
the second semiconductor die mounted in the second cavity.

41. A multiple chip system comprising:
a substrate having an upper surface and a lower surface;
two or more semiconductor die groups;
each die group comprising two or more semiconductor dies mounted to the upper surface, two or more semiconductor dies mounted to the lower surface such that the dies on the lower surface are vertically aligned with the dies on the upper surface, one or more first electrical pathways passing through the substrate between an outer edge of the substrate and a corresponding outer edge of at least one semiconductor die on the upper surface and a corresponding outside edge of the lower surface and a corresponding outer edge of at least one semiconductor die on the lower surface, one or more second electrical pathways passing through the substrate between an opposite outer edge of the substrate and a corresponding opposite outer edge of at least one semiconductor die on the upper surface and a corresponding opposite outer edge of the lower surface and a corresponding opposite outer edge of at least one semiconductor die on the lower surface, one or more third electrical pathways connecting at last one of the first electrical pathways to at least one of the semiconductor dies on the upper surface, one or more fourth electrical pathways connecting at least one of the first electrical pathways to at least one of the semiconductor dies on the lower surface, one or more fifth electrical pathways connecting at least one of the second electrical pathways with at least one of the semiconductor dies on the upper surface, one or more sixth electrical pathways connecting at least one of the second electrical pathways with at least one of the semiconductor dies on the lower surface.
